(19) United States
(12) Patent Application Publication
(10) Pub. No.: US 2017/0342558 A1
(43) Pub. Date: Nov. 30, 2017

(54) Deposition Method of Metallic Carbon Film

(71) Applicant: TES CO., LTD., Yongin (KR)

(72) Inventors: Jae-Young Yang, Suwon (KR); Sung-Woo Lee, Yongin (KR)

(73) Assignee: TES CO., LTD.

(21) Appl. No.: 15/606,705

(22) Filed: May 26, 2017

(30) Foreign Application Priority Data
May 27, 2016 (KR) 10-2016-0065742

(51) Int. Cl. C23C 16/453; C23C 16/34; C23C 16/18; C23C 16/06; C23C 16/455; C23C 4/134

(52) U.S. Cl. CPC C23C 16/453; C23C 16/4557; C23C 16/45519; C23C 4/134; C23C 16/18; C23C 16/06; C23C 16/34

(57) ABSTRACT

A deposition method of a metallic carbon film as use as a hard mask during a semiconductor process is provided. In detail, in order to overcome an issue in terms of patterning due to low etch selectivity when a conventional amorphous carbon layer is used as a hard mask and an issue in that the hard mask is not easily removed after etching is performed, a metallic carbon film is formed via a plasma-enhanced chemical vapor deposition (PECVD) method using a precursor containing metal and carbon to remarkably enhance etch selectivity, a grain size is reduced to amorphize the thin film so as to easily remove the hard mask after etching is performed, and relative contents of metal and carbon contained in the metallic carbon film are adjusted to remarkably lower overall internal stress of the metallic carbon film.

### CROSS-REFERENCE TO RELATED APPLICATIONS

This application claims priority from Korean Patent Application No. 10-2016-0065742, filed on May 27, 2016, in the Korean Intellectual Property Office, the disclosure of which is incorporated herein by reference in its entirety.

### TECHNICAL FIELD

Methods consistent with the present invention relate to a method of forming a metallic carbon film for use as a hard mask during a semiconductor process.

### RELATED ART

As patterns become minute in a semiconductor manufacturing process, the thickness of a photoresist is continuously reduced in order to ensure resolution of photolithography.

Accordingly, when an underlayer film as an etch target is thick, there is a problem in that a photosensitive film pattern is first removed or damaged to cause errors in patterns of the underlayer film and, accordingly, recently, an amorphous carbon layer (ACL) that is additionally formed below a photosensitive film has been mainly used as a hard mask.

However, with regard to a recent 3D vertical-NAND (V-NAND) flash memory, a DRAM capacitor process, or the like, precise control is needed by, for example, making critical dimension (CD) uniformity equal to or less than 0.5% in a substrate of an etching pattern while forming patterns with an aspect ratio (A/R) of 30:1 or more using an insulator film with a thickness of several micrometers (μm).

However, since a conventional ACL hard mask has insufficient etch selectivity with respect to an oxide film (SiO₂) as a level of 3 to 4:1, it is still difficult to embody patterns of an underlayer film and, accordingly, there has been an increasing need for a new hard mask material with high selectivity, for replacing with the ACL hard mask.

In order to overcome the above problem, a method of forming an ACL doped with nitrogen to enhance etch selectivity by additionally injecting hydrocarbon source gas containing nitrogen to increase density of a thin film during formation of the carbon layer has been developed.

However, since a monomer having a benzene structure is used as a precursor to form a significant amount of a porous structure in a thin film, there is a limit in enhancing density of the thin film and, accordingly, the method is insufficient to increase etch selectivity to a level that has been required recently.

In order to correspond to such a problem, a conventional metallic hard mask material has been reexamined

For example, a method of etching inter-metal dielectrics (IMD) using a tungsten film has been developed.

However, in this case, a deposited tungsten film has a columnar structure and a large grain size and, accordingly, there is a problem in that a lateral wall of an etched underlayer film pattern is roughened and etch residue is generated along with a grain boundary with a relatively high etch rate.

When the hard mask is removed after etching is performed, there is a problem in that it is difficult to remove the hard mask due to a large grain size of tungsten and a surface of an underlayer film with tungsten removed therefrom is also roughened.

Accordingly, in accordance with current trends, it is very difficult to apply the above method to a recent semiconductor manufacturing process of embodying ultra fine patterns.

### SUMMARY

Exemplary embodiments of the present invention overcome the above disadvantages and other disadvantages not described above. Also, the present invention is not required to overcome the disadvantages described above, and an exemplary embodiment of the present invention may not overcome any of the problems described above.

The present invention provides a deposition method of a metallic carbon film via a plasma-enhanced chemical vapor deposition (PECVD) method using a precursor containing metal and carbon in order to enhance etch selectivity of a hard mask material, which requires a very high value as the thickness of an underlayer film is increased.

The present invention also provides a deposition method of an amorphous tungsten carbonitride (WCₓN_{y}) film with a remarkably reduced grain size in order to overcome an issue of degrading critical dimension (CD) uniformity and etch uniformity in a substrate or between substrates during formation of fine patterns due to a grain size of tungsten in a process of etching an underlayer film using a conventional tungsten film as a hard mask and removing the hard mask.

The present invention also provides a deposition method of an amorphous tungsten carbonitride (WCₓN_{y}) film for adjusting relative content of metal and carbon included in a metallic carbon film to remarkably lower overall internal stress of a metallic carbon film.

According to an aspect of the present invention, a deposition method of a metallic carbon film on a heated substrate includes a first step of vaporizing a single precursor containing metal and carbon (C), a second step of supplying the vaporized single precursor to a reactor, and a third step of generating plasma in the reactor to decompose the vaporized single precursor and depositing the metallic carbon film on the heated substrate.

The metal of the single precursor may be tungsten (W).

The single precursor may further include nitrogen (N).

The single precursor may be TBIDMW [bis(tert-butyl-imido) bis(dimethyl-amido)tungsten].

The atomic percentage of the tungsten in the metallic carbon film may be 25% to 50%.

The grain size of the metallic carbon film may be equal to or less than 3 nm.

The metallic carbon film may include amorphous materials.

The metallic carbon film may include amorphous materials and crystalline materials simultaneously, wherein the amount of the amorphous materials in the metallic carbon film is greater than the amount of the crystalline materials.

The depositing of the metallic carbon film may be performed at a temperature of about 300° C. to about 550° C.

The supplying the vaporized single precursor to the reactor may include supplying inert gas containing at least one of helium (He) and argon (Ar) to the reactor along with the vaporized single precursor.

The metallic carbon film may be a hard mask film.

The method may further include, after the metallic carbon film is deposited, supplying helium (He) to the reactor to generate plasma.

At least one of the supplying amount of the single precursor in the first step and the plasma generating period in the third step is adjusted.

The supply amount of the single precursor may be periodically changed.

The periodically changing of the supply amount of the single precursor may include supplying a predetermined flow rate of the single precursor and non-supplying the single precursor.

The plasma may be constantly maintained during deposition of the metallic carbon film.

The supplying plasma and the non-supplying plasma may be periodically repeated during the deposition of the metallic carbon film.

The plasma generating period or the supply amount of the single precursor may be adjusted to control content of tungsten or carbon in the metallic carbon film.

The adjusting of the plasma generating period may include supplying the single precursor to the reactor when the plasma is supplied and non-supplying the single precursor to the reactor when the plasma is not supplied.

The method may further include, after the metallic carbon film is deposited, supplying helium (He) to the reactor to generate plasma.

Additional and/or other aspects and advantages of the invention will be set forth in part in the description which follows and, in part, will be obvious from the description, or may be learned by practice of the invention.

### BRIEF DESCRIPTION OF THE DRAWINGS

The above and/or other aspects of the present invention will be more apparent by describing certain exemplary embodiments of the present invention with reference to the accompanying drawings, in which:

FIG. 1 is a schematic diagram of a plasma-enhanced chemical vapor deposition (PECVD) device for forming a tungsten carbonitride film according to an exemplary embodiment of the present invention;

FIG. 2 is a flowchart of a process of forming a tungsten carbonitride film according to an exemplary embodiment of the present invention;

FIG. 3 is a diagram showing a structure of chemical bond of a precursor (TBIDMW) used to form a tungsten carbonitride film according to an exemplary embodiment of the present invention;

FIG. 4 is a graph showing content of a component according to a deposition temperature of a tungsten carbonitride (WCₓN_{y}) film and a CVD method;

FIG. 5A is a graph showing surface roughness of a thin film according to content of tungsten of a tungsten carbonitride (WCₓN_{y}) film and a CVD method and FIG. 5B is a graph showing surface roughness of a thin film according to a deposition temperature of a tungsten carbonitride (WCₓN_{y}) film and a CVD method;

FIG. 6A is a scanning electron microscopy (SEM) image, a Transmission Electron Microscope (TEM) image, and a x-ray diffraction (XRD) graph for analysis of crystallinity according to tungsten content of an tungsten carbonitride film and FIG. 6B is a schematic diagram showing a crystalline surface structure of a pure tungsten film;

FIG. 7 is a graph for comparison of an etch rate and etch selectivity between an existing carbon layer and a tungsten carbonitride (WCₓN_{y}) film according to the present invention;

FIG. 8A is a schematic cross-sectional view showing defects of underlayer film patterns when etching is performed using an amorphous carbon layer hard mask according to the prior art and FIG. 8B is a SEM image of an upper portion of the underlayer film patterns of FIG. 8A;

FIG. 9A is a schematic cross-sectional view showing underlayer film patterns when etching is performed using a hard mask according to an exemplary embodiment of the present invention and FIG. 9B is a SEM image of an upper portion of the underlayer film patterns of FIG. 9A;

FIGS. 10A to 10C are schematic diagrams of patterns of an initial state of etch (FIG. 10A), a state after etch is performed (FIG. 10B), and a state in which a hard mask is removed (FIG. 10C) when a conventional crystalline film is used as a hard mask; and

FIG. 11 is a schematic diagram of patterns in a state in which a hard mask is removed after etching is performed when the tungsten carbonitride (WCₓN_{y}) film according to the present invention is used as a hard mask.

### DETAILED DESCRIPTION

Certain exemplary embodiments of the present invention will now be described in greater detail with reference to the accompanying drawings.

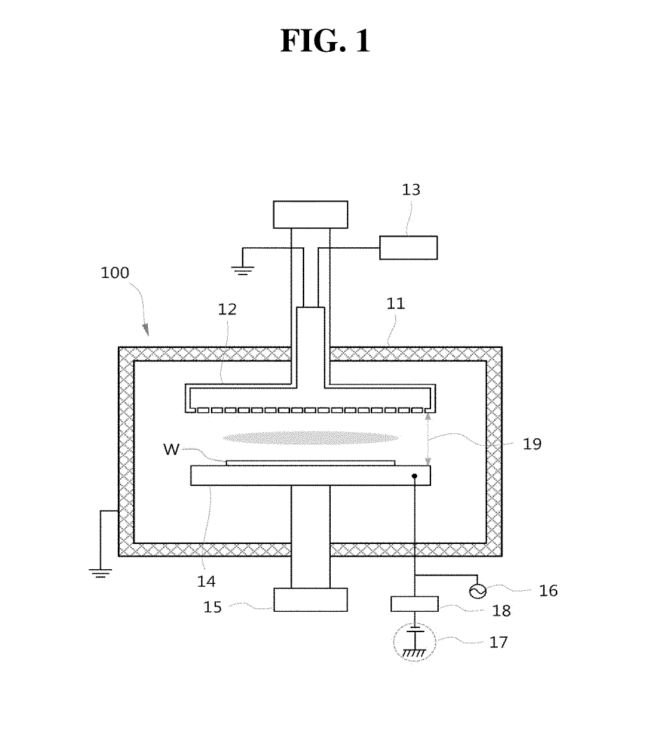

FIG. 1 is a schematic diagram of a plasma-enhanced chemical vapor deposition (PECVD) device 100 for depositing a metallic carbon film according to an exemplary embodiment of the present invention.

The PECVD device 100 includes a reactor 11, a shower head 12, a gas supply 13, a substrate support 14, a substrate support driver 15, and a high frequency (radio frequency; RF) power supply 16.

First, when a substrate W is placed on the substrate support 14 from the outside, an internal portion of the reactor 11 is adjusted to a vacuum state by an external vacuum system (not shown).

Then, the shower head 12 supplies process gas containing carrier gas and a precursor in a gas state, which are supplied through the gas supply 13 disposed above the reactor 11, into the reactor 11.

In this case, the gas supply 13 may further include a bubbler (not shown) or a liquid flow meter (LFM) (not shown) for vaporizing a precursor in a liquid state and, in the present embodiment, an inexpensive bubbler than an LFM is used, for example.

The bubbler maintains a precursor in a liquid state to a specific temperature of 120° C. to 160° C., vaporizes the precursor and, then, transmits the precursor to the gas supply 13, and the gas supply 13 adjusts process gas containing the vaporized precursor and carrier gas to a predetermined flow rate and supplies the process gas into the reactor 11 through the shower head 12.

The substrate support 14 includes a temperature adjuster disposed therein. In this regard, although, in the present embodiment, the RF power supply 16 and a direct current (DC) power supply 17 including a filter 18 may be electrically connected to the substrate support 14 and the shower head 12 is grounded, the RF power supply 16 may be electrically connected to the shower head 12, the substrate support 14 may be grounded, or the DC power supply 17 may be omitted, as necessary.

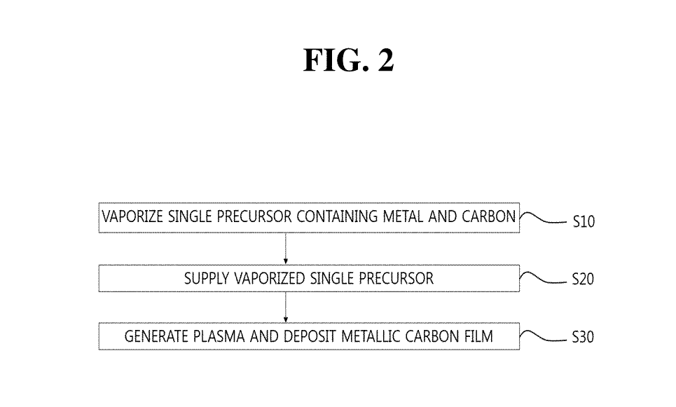

FIG. 2 is a flowchart of a process of forming a metallic carbon film according to an exemplary embodiment of the present invention. Hereinafter, for convenience of description, a method of forming a metallic carbon film will be described stepwise with reference to the flowchart.

(Operation S10: First Step of Vaporizing a Single Precursor Containing Metal and Carbon)

First, in operation S10 according to the present invention, when a substrate W is placed on the substrate support 14 in the reactor 11 and the substrate W is accommodated on the substrate W, an internal portion of the reactor 11 is adjusted to a vacuum state.

Then, a gap 19 between the shower head 12 and the substrate support 14 with the substrate W accommodated thereon is adjusted.

In this case, the substrate support 14 is pre-heated to maintain a substrate temperature in the range of 300° C. to 550° C. after the substrate W is placed

According to the present invention, a precursor that at least contains metal and carbon (C) as the process gas. For example, the metal may be tungsten (W) and, the precursor may further include nitrogen (N). In this case, when the precursor is used as process gas, even if process gas such as dopant gas that reacts with the precursor is not supplied, the same effect as in the case in which dopant is supplied into a thin film may be obtained, differently from the prior art. Accordingly, the precursor according to the present invention may be defined as a single precursor to which additional process gas such as dopant gas is not necessarily supplied.

That is, according to the prior art, in order to supply specific dopant into a metallic film, separate process gas containing the dopant needs to be further supplied to the reactor 11.

Accordingly, since a plurality of types of process gas needs to be supplied, costs are increased and the number of process parameters is also increased due to a complicated device structure and, thus, it is difficult to control composition of a thin film, thereby degrading process uniformity.

However, according to the present invention, since a single precursor containing tungsten, nitrogen, and carbon is used, even if separate dopant gas is not supplied, the same effect as in the case in which an internal portion of a metallic carbon film is doped with nitrogen and carbon may be obtained.

Accordingly, process parameters may be simplified, a component ratio of a thin film may be easily adjusted so as to remarkably enhance process uniformity, and a device structure may also be simplified using only a single vaporizer and, accordingly, device and process costs may be advantageously reduced.

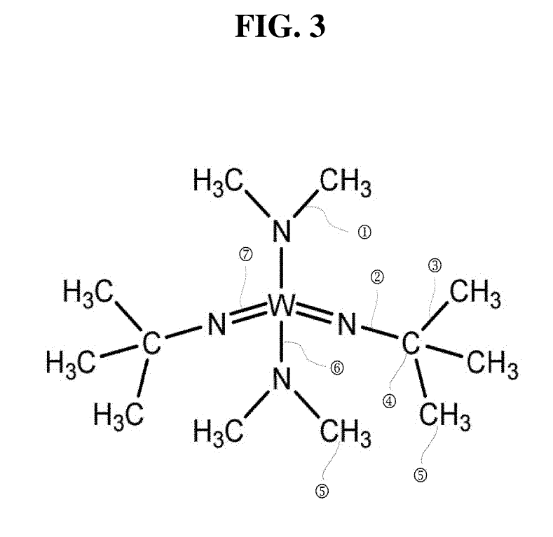

To this end, according to the present embodiment, as described above, TBIDMW [bis(tert-butyl-imido) bis(dimethyl-amido)tungsten (C₁₂H₃₀N₄W)] in a liquid state at room temperature is used as an example of a precursor containing tungsten, nitrogen, and carbon and FIG. 3 illustrates a structure of chemical bond of the precursor.

The TBIDMW precursor corresponds to a material formed via single bond of two nitrogen (N) atoms bonded with two methyl groups (CH₃) and double bond of two nitrogen atoms bonded with a tertiary butyl group (—C(CH₃)₃) to a tungsten (W) atom of a central part. When the TBIDMW precursor is used, the same tungsten carbonitride (WCₓN_{y}) film as a tungsten film doped with carbon nitride may be formed as a metallic carbon film.

The tungsten carbonitride (WCₓN_{y}) film may include a tungsten atom, a carbon atom, and a nitrogen atom and, when the number of a tungsten atom is 1, the thin film has x carbon atoms and y nitrogen atoms. In the present embodiment, when the tungsten carbonitride (WCₓN_{y}) film has one tungsten atom, x as the number of carbon atoms is equal to or greater than y as the number of nitrogen atoms.

In addition, although a process of depositing a tungsten carbonitride (WCₓN_{y}) film on a substrate using a TBIDMW precursor has been described with regard to the present embodiment, a precursor that includes a tungsten atom, a carbon atom, a hydrogen atom, and a nitrogen atom and is similar to a chemical structure of a TBIDMW precursor may also be used and a precursor containing metal and a carbon atom may also be used, as described above.

Accordingly, according to the present invention, the TBIDMW in a liquid state is vaporized by a bubbler of about 140° C. in the presence of carrier gas.

(Operation S20: Second Step of Supplying the Vaporized Single Precursor to the Reactor)

The vaporized TBIDMW precursor is supplied into the reactor 11 through the showerhead 12.

In this case, as described above, separate process gas for a reaction with the vaporized TBIDMW precursor is not additionally supplied.

In other words, a deposition method of the tungsten carbonitride (WCₓN_{y}) film according to the present embodiment is a process of depositing a thin film by supplying only the vaporized TBIDMW single precursor as process gas into the reactor 11, but not a process of forming a thin film by supplying the vaporized TBIDMW precursor process gas and process gas for a reaction with the TBIDMW precursor.

However, for stabilization of plasma discharge, inert gas such as helium (He) and argon (Ar) may also be supplied together.

The precursor may be various precursors (e.g., tungsten nitride) containing tungsten, nitrogen, and carbon without departing from the objective and effect of the present invention.

In addition, a precursor containing atoms (e.g., boron instead of carbon) other than nitrogen or carbon may also be used as long as the same or similar effect as doping with nitrogen and carbon contained in the precursor is obtained.

(Operation S30: Third Step of Generating Plasma in the Reactor to Decompose the Vaporized Single Precursor and Deposit the Metallic Carbon Film on the Heated Substrate)

When operation S20 is completed, the RF power supply 16 supplies power to the reactor 11 to generate plasma.

According to a condition of generating plasma for forming the tungsten carbonitride (WCₓN_{y}) film according to the present invention, the RF power supply 16 of 13.56 MHz supplies power of, for example, 100 watt (W) to 1500 W to the substrate support 14. With regard to a frequency, a frequency greater than 13.56 MHz, for example, a frequency equal to or greater than 27 MHz may also be used according to a process condition of deposition of a thin film.

In consideration of a relationship between the plasma discharge characteristics and a process pressure, a process pressure in the reactor may be set in the range between 1 Torr and 10 Torr.

It would be obvious to one of ordinary skill in the art that a process condition such as power of the RF power supply 16, a pressure, and a temperature may be appropriately changed according to the characteristics, thickness, and so on of a thin film as a deposition target. Although, according to the present embodiment, for convenience of description, operation S30 is performed after operation S20 is performed, the operations may be simultaneously performed.

Then, the process gas is discharged by generated plasma and a metallic carbon film, for example, the aforementioned tungsten carbonitride film is deposited on the substrate W.

As described above, when the RF power supply 16 supplies power to the substrate support 14 to generate plasma in the reactor 11, the TBIDMW precursor is decomposed in plasma to deposit a thin film on the substrate W.

Deposition of a thin film using the TBIDMW precursor is affected by various process parameters but is particularly affected by temperature change of the substrate W as an important parameter.

In general, a deposition reaction via decomposition of a precursor is overall proportional to temperature increase but has characteristics whereby decomposition efficiency is remarkably increased when a specific temperature is reached.

This is because bond between atoms is decomposed at the same time when energy equal to or greater than threshold energy for removing bond energy between atoms constituting a precursor is provided.

For example, when a substrate temperature is 450° C., bond between atoms with relatively low bond energy among atoms constituting a precursor is disconnected to contribute to deposition of a thin film and, then, when a substrate temperature is further increased to 550° C., bond between atoms with relatively high bond energy is disconnected to deposit a thin film.

As such, a precursor is incident on a substrate in a state of atoms or radicals that are decomposed and separated from bond due to temperature increase or is partially incident on the substrate in a state of non-decomposed neutral gas and is partially decomposed and then recombined to distribute to deposition of a thin film.

Accordingly, when change in decomposition efficiency according to adjustment of a deposition temperature using the precursor is used, content of a component contained in a thin film may be advantageously and easily changed.

A connection method of the RF power supply 16 may also be differently applied according to an ionization rate or decomposition efficiency of the process gas.

That is, for example, when the RF power supply 16 supplies power to the shower head 12 to generate plasma, the plasma is generated in an upper portion of the reactor 11 and, thus, as a distance by which reaction particles reach the substrate W is increased to increase collision probability, ionization rate or decomposition efficiency according to high energy electron is increased.

On the other hand, when the RF power supply 16 supplies power to the substrate support 14 to generate plasma, ionization rate or decomposition efficiency of particles in the plasma is reduced but a ratio at which the particles are incident on a substrate is high and reaction probability with the substrate is increased due to the characteristics of the particles adjacent to the substrate W and, accordingly, an effect of increasing density of a thin film may be obtained.

However, the aforementioned discharge effect has no difference when a single precursor according to the present invention is used and, thus, a power supply method of the RF power supply 16 is not limited and is advantageously applied to a plasma generating apparatus with various configurations.

Hereinafter, a method of forming an optimum tungsten carbonitride (WCₓN_{y}) film according to the present invention using a comparison evaluation result of a process condition, a forming method, and so on during formation of the tungsten carbonitride (WCₓN_{y}) film will be described.

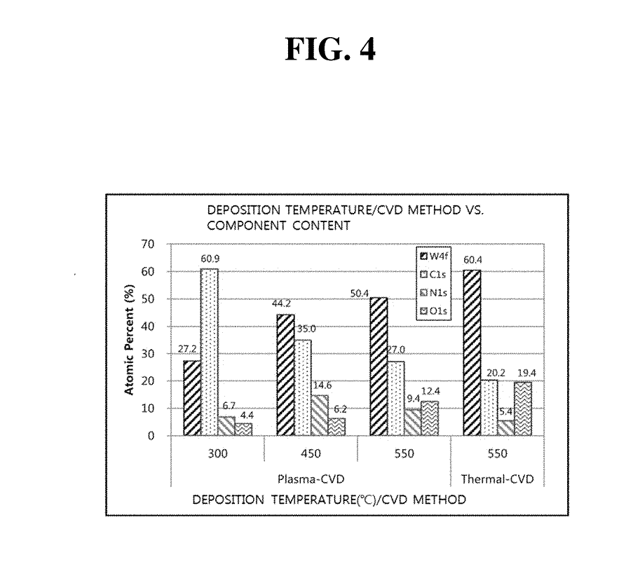

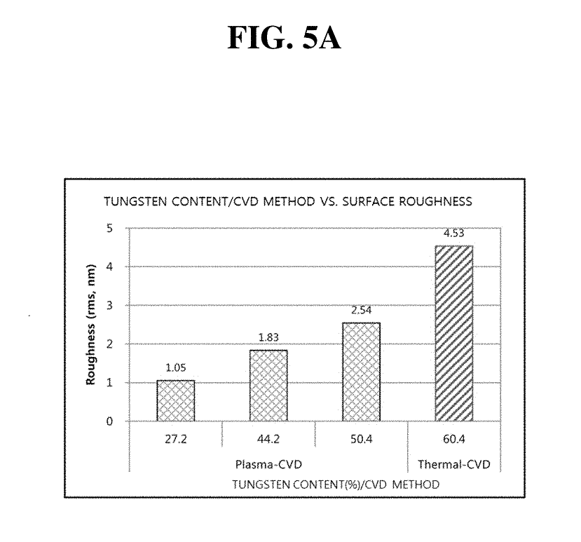

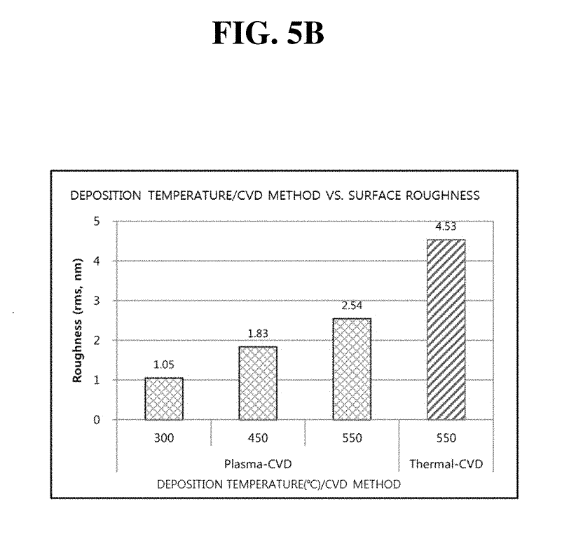

FIG. 4 is a graph showing content of a component according to a deposition temperature of a tungsten carbonitride (WCₓN_{y}) film and a CVD method. FIG. 5A is a graph showing surface roughness of a thin film according to content of tungsten of a tungsten carbonitride (WCₓN_{y}) film and a CVD method. FIG. 5B is a graph showing surface roughness of a thin film according to a deposition temperature of a tungsten carbonitride (WCₓN_{y}) film and a CVD method.

Content of components in the thin film illustrated in FIGS. 4, 5A, 5B, and 6A refers to atomic percent.

In addition, percent or content according to the present embodiment refers to atomic percent (content) of each component in a thin film without particular description.

In general, in a thermal-CVD method, a deposition process is performed at a higher temperature and higher pressure than a plasma-enhanced CVD (hereinafter, PECVD) method.

In the present embodiment, in order to compare tungsten content in a thermal-CVD method and a PECVD method, the thermal-CVD method and the PECVD method are separately performed at a process temperature of 550° C. to deposit a thin film.

As shown in FIGS. 4 and 5A, as a comparison result of tungsten content in a thin film deposited using the thermal-CVD method and the PECVD method at 550° C., the thermal-CVD method tends to have high tungsten content (atomic percent) of about 10% compared with the PECVD method.

FIG. 5B is a diagram showing a root mean square (RMS) value indicating surface roughness of a thin film and, in this case, RMS values of thin films deposited using a PECVD method at 300° C., 450° C., and 550° C. are 1.05 nm, 1.83 nm, and 2.24 nm, respectively.

It may be seen that surface roughness of a thin film deposited using a PECVD method is increased with increase in temperature and, as a comparison result of a difference in an RMS value of a thin film in a range of 300° C. and 450° C. and in a range of 450° C. and 550° C., it may be seen that surface roughness of the thin film is increased to a relatively small RMS value equal to or less than 1 nm.

An RMS value of a thin film that is deposited using a PECVD method at 550° C. is 2.54 nm and an RMS value of a thin film that is deposited using a thermal-CVD method at 550° C. is 4.53 nm.

As seen from these RMS values, the surface roughness of the thin film deposited using a thermal-CVD method is much greater than the surface roughness of the thin film deposited using a PECVD method at 550° C.

Increase in surface roughness according to increase in content of tungsten in a thin film indicates that the thin film is crystallized via growth of grains and, as described above, a thermal-CVD method has a problem in that a thin film is crystallized to make an etching process as a subsequent process more difficult and, thus, the thermal-CVD method is not an appropriate deposition method.

FIGS. 5A and 5B are graphs showing tungsten content and temperature according to an RMS value measured via comparison.

In detail, the graphs shows, with regard to a PECVD method, a deposition temperature of 300° C. and W27.2% in the case of an RMS value of 1.05 nm, a deposition temperature of 450° C. and W44.2% in the case of an RMS value of 1.83 nm, and a deposition temperature of 550° C. and W50.4% in the case of an RMS value of 2.54 nm, and shows, with regard to a thermal-CVD method, a deposition temperature of 550° C. and W60.4% in the case of an RMS value of 4.53 nm.

In the PECVD method, as a deposition temperature is increased and tungsten content is increased, an RMS value is increased. Highest roughness as an RMS value of 4.53 nm corresponds to tungsten content of 60.4% at a process temperature of 550° C. in the thermal-CVD method.

As seen from the result, particles of a thin film deposited using the thermal-CVD method is grown with a much larger grain size than that of particles required for a recent etching process for forming fine patterns to achieve crystallinity.

This indicates that the thin film is crystallized and, as described above, there is a problem in that the etching process as a subsequent process becomes more difficult due to the crystallized grain size and, accordingly, the thermal-CVD method is not an appropriate deposition method.

In addition, the thermal-CVD method shown in FIG. 4 has increased concentration of oxygen (O1s) in a thin film compared with the PECVD method.

Presence of oxygen in a thin film is not caused by decomposition of the process gas (the precursor does not contain oxygen) and oxygen dipped in an internal wall of a reactor, and so on is discharged according to increase in deposition temperature and penetrates into the thin film and, in this regard, the oxygen is considered as a type of impurities.

Accordingly, it may be seen that, under the same process condition, the PECVD method according to the present invention has excellent thin film characteristics compared with the thermal-CVD method.

Accordingly, hereinafter, change in characteristics of a thin film according to change in process condition when the PECVD method is applied will be described.

As seen from FIG. 4, as an analysis result of tungsten content as a deposition temperature is increased to 450° C. from 300° C. and increased to 550° C. from 450° C., tungsten content is W27.2% at 300° C., W44.2% at 450° C., and W50.4% at 550° C. and, accordingly, tungsten content tends to be increased until a deposition temperature is increased to at least 550° C.

Tungsten content in a thin film is increased due to increase in decomposition efficiency of a precursor according to increase in deposition temperature and, as described above, etch selectivity of a thin film is increased as tungsten content is increased, but the thin film is formed as a crystalline structure with a large grain size and, accordingly, there is a problem in that it is difficult to remove the thin film in a subsequent process.

Accordingly, tungsten content is maintained in an appropriate level in a thin film to amorphize the thin film and to reduce a grain size and, accordingly, it is important to harmonize increase in etch selectivity and easy removal of a thin film.

As shown in FIG. 4, carbon content tends to be continuously reduced according to increase in deposition temperature oppositely to tungsten, which is determined to relate to the fact that C—N (305 kJ/mol), C—C (348 kJ/mol), and C—H (412 kJ/mol) bonds among components constituting the precursor are decomposed with increase in temperature in the stated order in which bond energy is increased.

That is, when a deposition temperature is low, atoms constituting the precursor contribute to deposition in a state in which most atoms are not decomposed (e.g., a state in which a large amount of neutral molecules are present) and, accordingly, content of tungsten is low and content of carbon is relatively high according to a ratio of atoms constituting the precursor molecules.

Then, when a decomposition temperature is reached to a predetermined level, as shown in structural formula of chemical bond of FIG. 3, C—N bond with low bond energy is disconnected such that a methyl group (—CH₃, \hat{1}) or a butyl group (—C(CH₃)₃, \hat{2}) is decomposed and C—C bond (\hat{3}) is re-disconnected such that single carbon (\hat{4}) in a central part of a butyl group is discomposed but, since only single carbon (\hat{4}) in the central part of a butyl group is decomposed before C—H bond (\hat{5}) with higher bond energy is decomposed, only a small amount of carbon is decomposed.

Accordingly, tungsten content is increased but carbon content is relatively reduced and, in this case, nitrogen behaves together with tungsten and, accordingly, it deems that relative content of nitrogen is increased only by a small amount.

When a deposition temperature is further increased, C—H bond (\hat{5}) with high bond energy is decomposed to generate a large amount of carbon but a significant amount of carbon of the generated carbon is bonded with the precursor or hydrogen (H) or oxygen (O) outgassing from the internal wall of the reactor to form methane (CH₄) gas, carbon monoxide (CO) gas, or the like, the gas is discharged out of the reactor and, accordingly, content of carbon in the thin film is continuously reduced.

As shown in FIG. 4, nitrogen content according to a deposition temperature tends to be increased to 14.6% at 450° C. from 6.7% at 300° C. and, then, to be re-reduced to 9.4% at 550° C. from 450° C. as a starting point.

Nitrogen content is increased at a temperature equal to or less than 450° C. for the following reason. Since bond energy (423 kJ/mol) of single bond (W—N, \hat{6}) between nitrogen and tungsten is high and double bond (W═N, \hat{7}) is higher than single bond, it is not easy to decompose double bond and, thus, most nitrogen is deposited on a thin film in a state in which nitrogen is single or double-bonded with tungsten.

However, when temperature is further increased to 550° C. nitrogen (\hat{5}) single-bonded with tungsten is partially decomposed and most nitrogen double-bonded with tungsten is deposited on a thin film and, accordingly, nitrogen content is lower than carbon.

In addition, when nitrogen is decomposed from W—N bond (\hat{6}) at 550° C., C—H bond (412 kJ/mol) with slightly low bond energy compared with W—N bond is also decomposed to discharge hydrogen and the decomposed nitrogen and hydrogen are recombined to form and discharge gas such as ammonia (HN₃) and, accordingly, it deems that content of nitrogen in a thin film is further reduced instead.

In general, it is known that a nitrogen component in a thin film does not largely affect crystallinity but obstructs crystallization of other components. Accordingly, maximum nitrogen content is exhibited at the deposition temperature of about 450° C. and, accordingly, the temperature is considered as a temperature range in which an amorphous thin film is advantageously formed.

As a result, as seen from the evaluation, a condition for forming the tungsten carbonitride (WCxNy) film according to the present invention is advantageously obtained in a range around 450° C. based on contents of tungsten, nitrogen, and carbon.

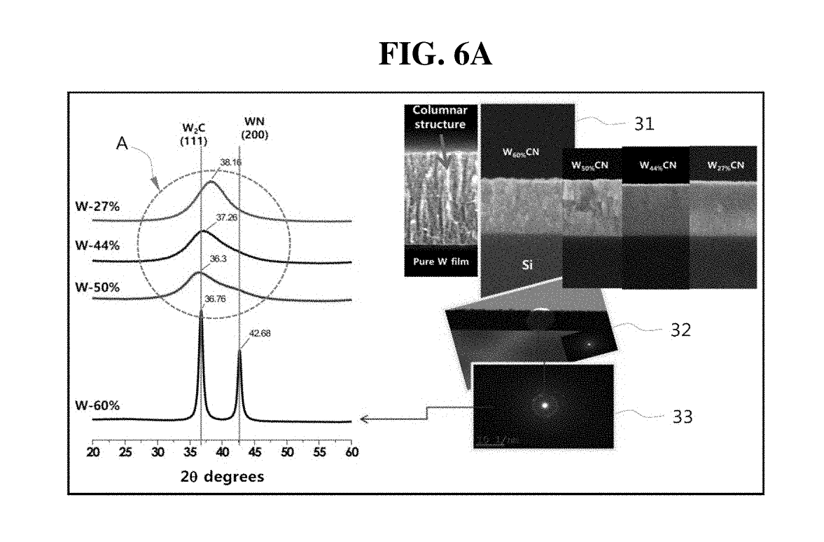

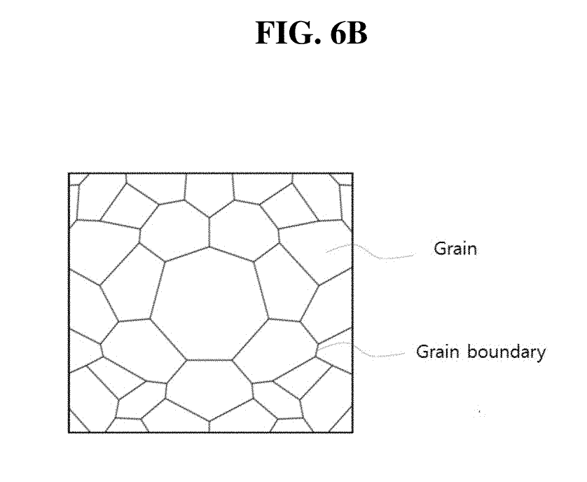

FIG. 6A is a scanning electron microscopy (SEM) image (right portion) and an XRD graph (left portion) for analysis of crystallinity according to tungsten content of an amorphous tungsten carbonitride (WCₓN_{y}) film according to the present invention.

First, as seen from the SEM image, a pure tungsten film is formed as a columnar grain structure. As shown in FIG. 6B, the grain internal structure has a dense and hard structure but the grain boundary has a non-dense structure to function as a migration pathway of a material and has a high etch rate due to vulnerable structural characteristics.

As described above, crystalline tungsten has a problem in that roughness or striation of a lateral wall and a pattern surface is generated due to an etch rate difference with a grain boundary and etching is difficult because an internal portion of grain is almost occupied and, accordingly, it is difficult to remove a thin film.

Although a crystalline degree is relatively weak compared with pure tungsten, it may be seen that the aforementioned crystalline structure is also present in a W60.4% CN (tungsten carbonitride (WCₓN_{y}) film containing 60.4% of tungsten) film formed using a thermal-CVD method and a W50.4% CN film formed using the PECVD method.

However, in the case of W44.2% CN and W27.2% CN formed using the PECVD method, it may be seen that a crystalline structure of a thin film is removed and amorphized.

As seen from the XRD graph, the above fact may be obviously seen from change in X-ray diffraction patterns of a thin film according to reduction in tungsten content.

That is, when a tungsten carbonitride (WCₓN_{y}) film deposited using a thermal-CVD method contains 60.4% of tungsten, intensity of a W₂C 111 peak and a WN 200 peak which are characteristic peaks of the tungsten carbonitride (WCₓN_{y}) film is high and a peak width (full width at half maximum (FWHM)) is sharp.

On the other hand, when the thin film deposited using a PECVD method contains 50.4% or less of tungsten, intensity of a W₂C 111 peak is weak and a peak width is broad and diffused. The above fact may be seen again from this characteristic.

In this regard, whether crystallization is achieved according to a shape of an XRD characteristic peak will be described below.

A crystalline material is configured by periodically arranging atoms in a 3D space, whereas an amorphous material is configured by randomly arranging atoms without such periodicity.

Accordingly, in the case of a crystalline material, an X ray emitted by an XRD apparatus is intensively scattered and detected at a specific degree (20 degree) due to the periodicity of the crystalline material and, accordingly, the X-ray has high peak intensity and a narrow peak width.

On the other hand, in the case of an amorphous material, an X ray is scattered in various directions and diffraction patterns are detected at an angle in a relatively wide range and, accordingly, the X ray has low peak intensity and a wide peak width.

Accordingly, in general, reduction in peak intensity and increase in peak width under the same condition means that crystallinity in a thin film is weakened, that is, is amorphized to reduce a grain size.

As a result, it deems that a thin film containing 50.4% or less of tungsten, which is deposited using a PECVD method, is amorphized compared with a thin film containing of 60.4% of tungsten, which is deposited using a thermal-CVD method.

In particular, as seen from an upper-right SEM image 31 of FIG. 6A, a thin film (W60% CN) containing of 60.4% of tungsten exhibits the crystallinity of a columnar structure and, as seen from lower-right TEM images 32 and 33, dot patterns are also formed at an equivalent interval to achieve crystallinity via diffraction grating analysis.

As seen from an XRD graph (part A) of the PECVD method according to the present invention in FIG. 6A, as tungsten content is reduced to 27% from 50%, a W₂C 111 peak as a characteristic peak is moved in a right direction, that is, toward a WN 200 peak and a diffraction angle (20 degree=36.76, 37.26, and 38.16) is increased.

Movement of a peak in a right direction, that is, increase in 20 degree value means that an interval between particles is reduced and a thin film is amorphized because a lattice plane interval d is reduced according to Bragg's equation; 2d sin θ=nλ (λ: wavelength of X ray, n: integer).

As a result, nitrogen (N) and carbon (C) coexist with tungsten interstitial sub-lattices in a region between binary W₂C 111 and WN 200 peaks to form ternary amorphous tungsten carbonitride (WCₓN_{y}) according to the present invention and atomic percent of tungsten for amorphization of the thin film may be equal to or greater than 25% and less than 50%.

In this case, the tungsten carbonitride (WCₓN_{y}) film may be most amorphized in the film but may partially include crystalline parts and, in this case, an amount of amorphous materials is larger than that of crystalline materials.

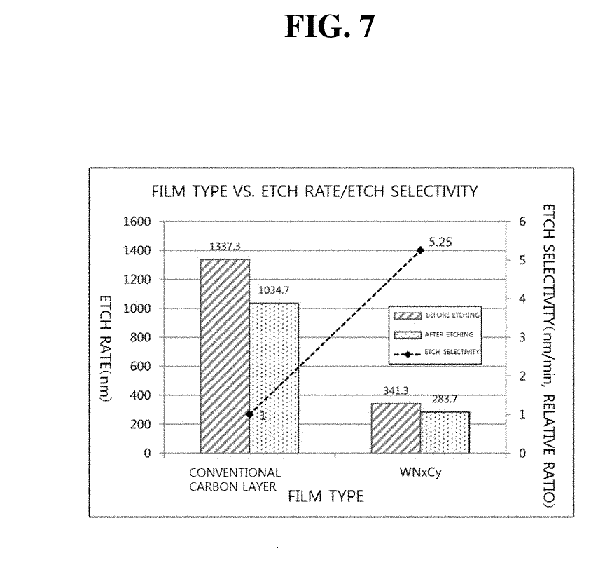

FIG. 7 is a graph for comparison of an etch rate and etch selectivity between an existing amorphous carbon layer and a tungsten carbonitride (WCₓN_{y}) film formed using the above method according to the present invention.

Based on the case in which an existing amorphous carbon layer is used as a hard mask, when a tungsten carbonitride (WCₓN_{y}) film according to the present invention is used as a hard mask, it may be seen that etch selectivity is increased by about five times or more.

Accordingly, when the tungsten carbonitride (WCₓN_{y}) film according to the present invention is used as a hard mask, remarkably enhanced etch selectivity may be obtained and, thus, the thickness of the hardness may be reduced and, accordingly, process margin may be increased and remarkably excellent pattering characteristics may be ensured compared with a conventional case in an etch process of ultra fine patterns.

A relatively thick hard mask may be required according to a semiconductor manufacturing process and, in this case, when the hard mask film is formed via the aforementioned process, a grain size of a crystal to be contained in the hard mask film may be increased in proportion to the thickness of the hard mask film.

For example, when a grain size of the crystal is larger than 3 nm, etch selectivity may be enhanced but a crystalline structure with a large grain size is formed and, accordingly, the structure is not easily removed in a subsequent process. In addition, as a grain size is increased, surface roughness of the hard mask film tends to be further increased.

Accordingly, when a metallic carbon film with a desired thickness is formed as a hard mask film on the substrate, deposition may be performed so as to adjust a grain size of crystals to be contained in the metallic carbon film.

For example, at least one of a supply amount of a single precursor containing metal and carbon and a plasma generating period may be adjusted and a metallic carbon film may be deposited.

As such, when a supply amount of a single precursor is adjusted or a plasma generating period is adjusted, the thickness of the metallic carbon film may be prevented from being continuously grown. That is, the metallic carbon film may be grown to a predetermined thickness and, then, may stop being grown and may be re-grown. In this case, a grain size of the metallic carbon film may be prevented from being increased to 3 nm or more. The metallic carbon film stops being grown and is re-grown rather than being continuously grown and, thus, a grain size of the crystalline material may be maintained to 3 nm or less.

In this case, a thickness to which the metallic carbon film is grown may be determined according to metallic atomic percent contained in the metallic carbon film.

That is, when the single precursor contains tungsten (W), nitrogen (N), and carbon (C), the thickness of the metallic carbon film may be determined to have tungsten atomic percent of 25% to 50%.

When the metallic carbon film has the aforementioned metallic atomic percent, a grain size of the metallic carbon film may be equal to or less than 3 nm.

That is, an amorphous material and a crystalline material coexist in the metallic carbon film and, when the metallic carbon film includes the crystalline material, the particles may be formed to a grain size of 3 nm or less. In addition, the metallic carbon film may be formed such that the amorphous material has a larger amount than that of the crystalline material. As such, when the amorphous material has a larger amount than that of the crystalline material, patterns with a desired shape may be obtained during formation of a fine pattern in a subsequent photolithography process.

In detail, adjusting of a supply amount of a single precursor containing metal and carbon may include periodically changing the supply amount of the single precursor. That is, an operation in which a predetermined flow rate of single precursor is supplied and an operation in which a predetermined flow rate of single precursor is not supplied may be repeatedly performed or the supply amount of the single precursor may be periodically changed.

In this case, generation of plasma may be constantly maintained. For example, power of the RF power supply 16 may be continuously supplied to the substrate support 14.

That is, while generation of plasma is maintained, if the operation in which a predetermined flow rate of single precursor is supplied and an operation in which a single precursor is not supplied are repeatedly performed, the metallic carbon film is deposited during supply of the single precursor. Accordingly, as described above, the metallic carbon film may be grown stepwise rather than being continuously grown.

In addition, when an operation in which a predetermined flow rate of single precursor is supplied and an operation in which a predetermined flow rate of single precursor is not supplied are repeatedly performed, a flow rate of the single precursor may be changed. That is, in the operation in which the single precursor is supplied, a supply amount of the single precursor may be changed compared with a previous supplying operation.

In this case, when a single precursor with an increased supply amount is supplied to a reactor, content of metal, i.e., tungsten of a deposited thin film is increased compared with carbon content. In addition, when a vaporized single precursor with a reduced supply amount is supplied to the reactor, content of tungsten of the deposited thin film is lowered compared with carbon content.

In this case, relative content of metal contained in the metallic carbon film and relative content of carbon may be adjusted to adjust overall internal stress of the metallic carbon film.

That is, when content of metallic atomic percent of the metallic carbon film is relatively increased, tensile stress may act and, on the other hand, when carbon atomic percent is relatively increased, compressive stress may act.

Accordingly, when relative contents of metal and carbon contained in the metallic carbon film are adjusted, the tensile stress and the compressive stress may conflict with each other to adjust overall internal stress of the metallic carbon film.

While generation of plasma is maintained, if the vaporized single precursor with an increased supply amount is supplied to a reactor, content of metal, that is, tungsten of a deposited thin film is increased compared with content of carbon. On the other hand, while generation of plasma is maintained, if the vaporized single precursor with a reduced supply amount is supplied to a reactor, content of tungsten of a deposited thin film is reduced compared with content of carbon. In this case, like in the aforementioned case, internal stress (tensile and compressive stress) may be adjusted. As such, as the internal stress is adjusted, overall internal stress of a metallic carbon film may be remarkably reduced, thereby preventing warpage of a substrate.

When the precursor gas and the inert gas are continuously supplied with a predetermined flow rate to the reactor 11, the operation in which plasma is supplied and the operation in which plasma is not supplied may be periodically repeated. In this case, when plasma is supplied, the single precursor may be supplied to the reactor and, when plasma is not supplied to the reactor, the single precursor may not be supplied to the reactor.

For example, when a thin film is deposited on the substrate while high frequency power is supplied to supply plasma and the metallic carbon film is deposited to a predetermined thickness on the substrate, the high frequency power is not supplied and, thus, the metallic carbon film may not be deposited any longer, thereby preventing a grain size of a crystalline material to be contained in the metallic carbon film from being increased to a predetermined grain size, e.g., 3 nm or more.

In this case, a time period (hereinafter, referred to as “off time”) of an operation in which plasma is not supplied (an operation in which high frequency power is not supplied) may not be relatively too short. That is, when the off time is too short, a time period in which plasma is not supplied is highly reduced to achieve an effect of continuously supplying plasma. In this case, the metallic carbon film may be continuously grown such that the aforementioned grain size is further increased to a predetermined size, e.g., 3 nm or more. Accordingly, the off time may be set to about 0.1 second or more and set to 0.5 to 1 second.

In the operation in which plasma is supplied, relative contents of metal and carbon contained in the metallic carbon film may be adjusted according to power supplied from the high frequency power supply.

For example, when power supplied from the high frequency power supply is relatively low, the metallic atomic content is relatively increased. On the other hand, when power supplied from the high frequency power supply is relatively high, carbon atomic percent is relatively increased. Accordingly, as described above, internal stress of the metallic carbon film may be adjusted.

As a result, according to the present embodiment, the plasma generating period or the supply amount of the precursor may be adjusted and, thus, content of tungsten or carbon in the metallic carbon film may be adjusted. Accordingly, internal stress of the metallic carbon film may be adjusted.

The metallic carbon film may be deposited and, then, helium (He) as inert gas may be supplied to the reactor to generate plasma so as to perform subsequent processes.

In this case, while He is supplied, the RF power supply 16 may supply power of 800 W to 1600 W to the substrate support 14. In addition, a process pressure in the reactor may be maintained at 1 torr to 10 torr.

Under the above process condition, plasma treatment may be performed for a time period of about 1 second to 10 seconds. In this case, a substrate temperature may be the same as a temperature of a substrate on which the aforementioned metallic carbon film is deposited and may be maintained at about 300° C. to 550° C.

In this case, He may solidify the metallic carbon film so as to reduce defects of the metallic carbon film. While density of the metallic carbon film is increased, a grain size of the metallic carbon film may be adjusted to 3 nm or less.

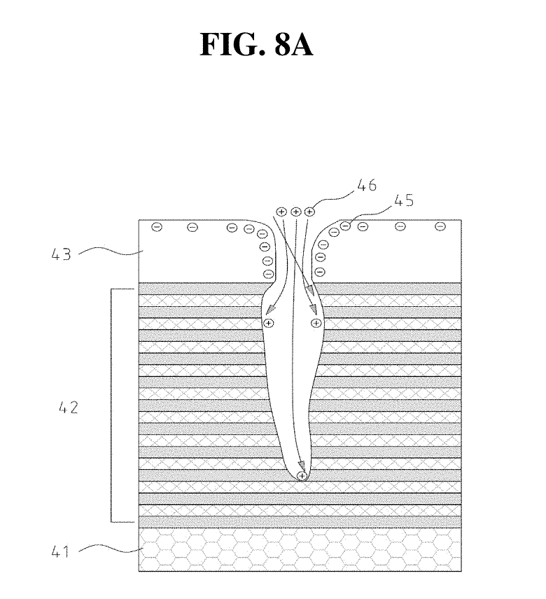

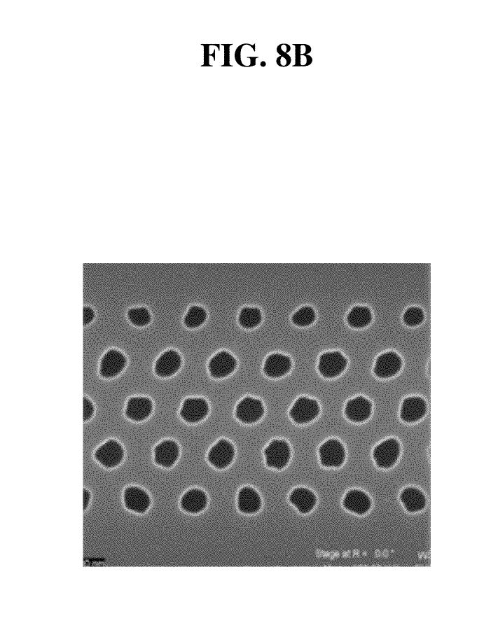

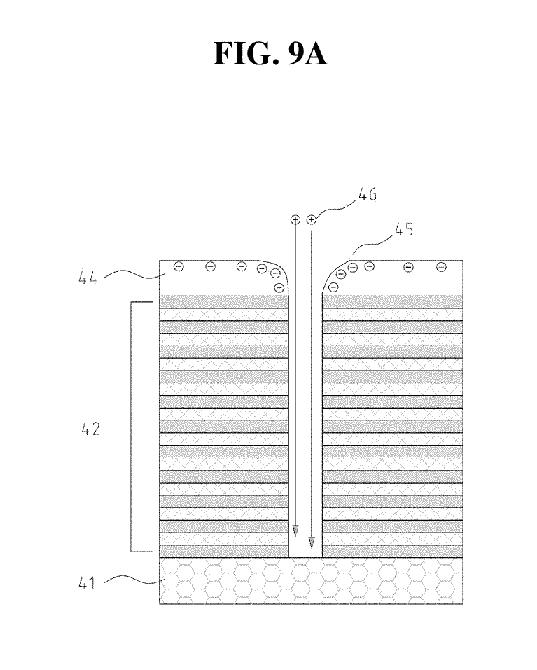

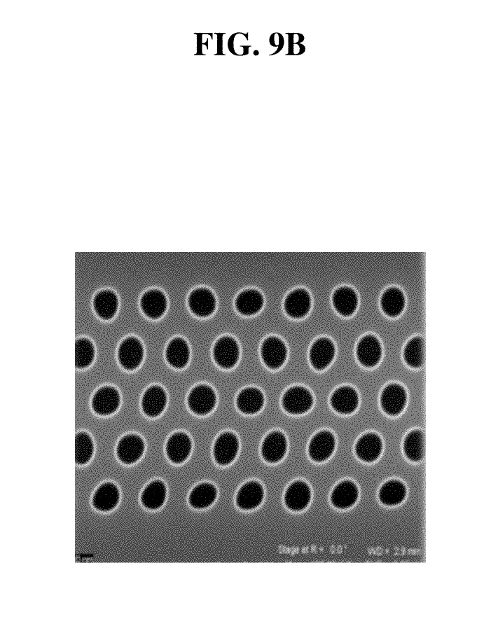

FIGS. 8A and 8B are a schematic cross-sectional view showing defects of underlayer film patterns and an SEM image of an upper portion of the underlayer film patterns, respectively, when etching is performed using an amorphous carbon layer hard mask according to the prior art. FIGS. 9A and 9B are a schematic cross-sectional view showing underlayer film patterns and an SEM image of an upper portion of the underlayer film patterns, respectively, when etching is performed using a hard mask according to an exemplary embodiment of the present invention.

As shown in FIGS. 8A and 8B, when an underlayer film 42 with an ON structure formed by alternately stacking an oxide layer and a nitride layer is etched using an amorphous carbon layer 43 according to the prior art as a hard mask, there is a problem in that an etch profile of the underlayer film 42 is poor and shapes of hole patterns are not uniform.

It is known that this phenomenon is related to plasma charging damage because, when the amorphous carbon layer 43 according to the prior art is used as a hard mask, the hard mask needs to be thick due to low etch selectivity with respect to the underlayer film 42 and, thus, a surface area of the hard mask exposed to plasma is increased to increase charging.

That is, when a substrate is exposed to plasma for a long time during an etching process, a large amount of electrons 45 that are rapidly and isotropically incident on a surface of the substrate accumulate on the exposed surface of the hard mask 43 to negatively (−) charge the surface due to a difference of incident angular distribution between electrons and ions.

Then, the accumulating electrons obstruct incidence of ions 46 (electron shading effect) to cause ion trajectory deflection and, accordingly, undercut of an upper portion of etch patterns or bowing and bending of a lateral wall are caused.

In addition, the accumulating electrons act as attractive act with respect to ions with high energy for overcoming the above electron shading effect to accelerate ions to a bottom surface of etch pattern, thereby causing damage such as micro-trenching.

On the other hand, as shown in FIGS. 9A and 9B, when the underlayer film with an ON structure is etched using the tungsten carbonitride (WCₓN_{y}) film according to an exemplary embodiment of the present invention as a hard mask, the underlayer film may be uniformly etched with a desired pattern shape up to a lower layer 41 of a stack structure and the hole pattern shape may be uniform.

This is because, as described above, as etch selectivity is increased to reduce the thickness of the hard mask, a surface area of the hard mask, which is exposed to plasma and on which electrons accumulate during an etching process, is reduced and, thus, the plasma charging damage is remarkably reduced.

In addition, since the tungsten carbonitride (WCₓN_{y}) film according to an exemplary embodiment of the present invention contains a large amount of tungsten as metal, a significant amount of accumulating electrons are distributed along metal (tungsten) conductors that are uniformly distributed in the thin film rather than being concentrated on a specific portion of a surface of a hard mask film, thereby partially preventing electric charges from being concentrated, differently from a conventional pure insulating hard mask film.

Accordingly, as shown in FIG. 9B, the tungsten carbonitride (WCₓN_{y}) film according to the present invention reduces the above plasma charging damage to advantageously and remarkably enhance a profile of a profile of etch patterns.

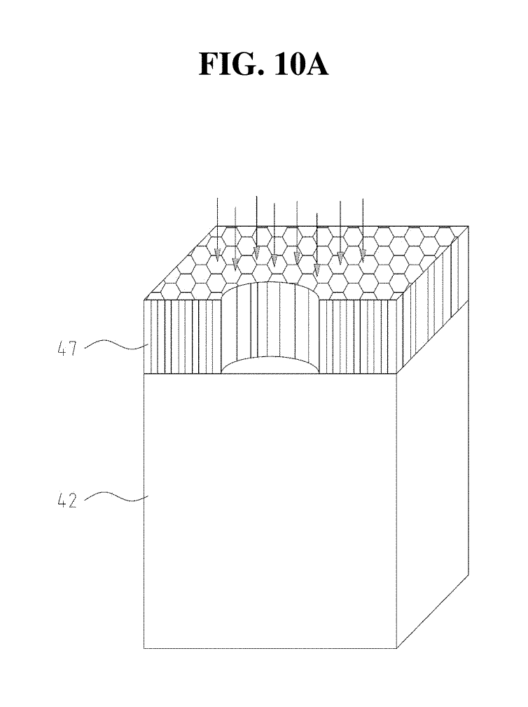

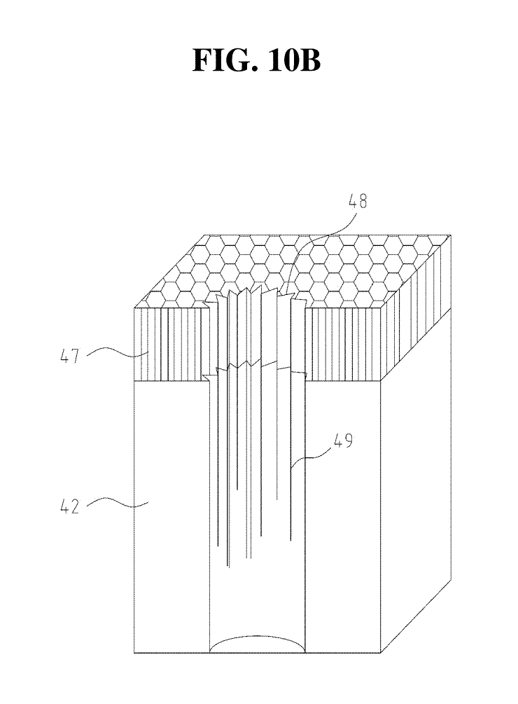

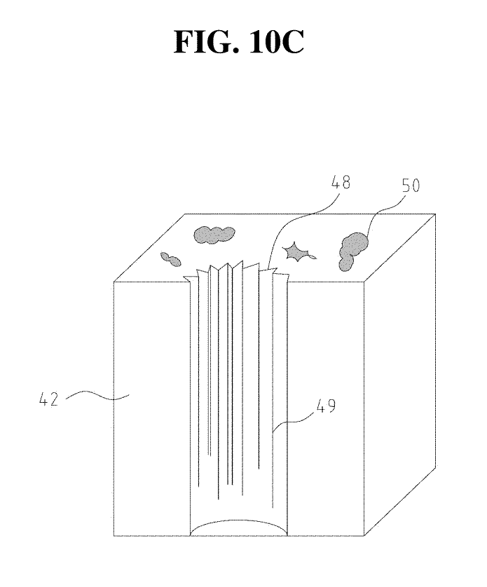

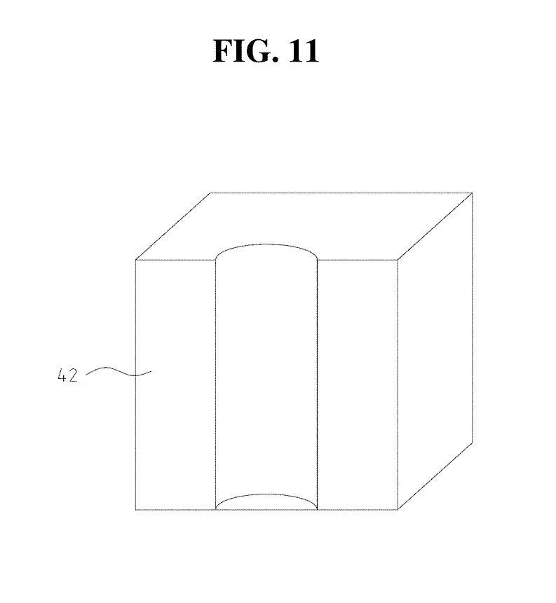

FIGS. 10A to 10C are schematic diagrams of patterns of an initial state of etch (FIG. 10A), a state after etch is performed (FIG. 10B), and a state in which a hard mask is removed (FIG. 10C) when a conventional crystalline film is used as a hard mask. FIG. 11 is a schematic diagram of patterns in a state in which a hard mask is removed after etching is performed when the tungsten carbonitride (WCₓN_{y}) film according to the present invention is used as a hard mask.

As shown in FIGS. 10A to 10C, when etching is performed using a crystalline film configured with large crystals larger than 3 nm as a hard mask 47, there is a problem in that a pattern surface 48 and a lateral wall 49 of the underlayer film 42 are roughened or striation is generated due to an increased etch rate at a grain boundary and a ratio of an internal portion of a grain to the grain boundary is very high and, accordingly, there is a problem in that it is not easy to remove the crystalline hard mask film 47 due to difficult etching and residue 50 remains on etch patterns.

On the other hand, as shown in FIG. 11, the tungsten carbonitride (WCₓN_{y}) film according to the present invention has the characteristics whereby amorphous materials with a grain size of 3 nm or less are present or amorphous materials and crystalline materials with 3 nm or less coexist and, accordingly, it is advantageous that a hard mask is easily removed after etching is performed and the issues in terms of roughness of a surface or lateral surface of etched patterns or damage such as striation are remarkably overcome.

The tungsten carbonitride (WCₓN_{y}) film according to the present invention is deposited using a single organic metallic nitride precursor and, thus, a process and a device may be advantageously simplified so as to reduce costs and to enhance productivity.

The method of forming the tungsten carbonitride (WCₓN_{y}) film according to the present invention and a hard mask material using the method may be applied to various fields of a semiconductor process and, in particular, may be variously applied irrespective of a type of a thin film in sputtering of a semiconductor front-end manufacturing process such as a deposition process related to increase in etch selectivity of a thin film.

According to the diverse exemplary embodiments of the present invention, as described above, in the deposition method of the metallic carbon film according to the present invention, high etch selectivity of 10:1 or more compared with an oxide layer or a nitride layer may be obtained so as to remarkably reduce the thickness of a hard mask in an etch process with a high aspect ratio (A/R) of 30:1 or more. Accordingly, it may be advantageous that CD uniformity is enhanced and productivity is enhanced by reducing a deposition time period.

Differently from the conventional case, a hard mask material is configured in such a way that amorphous materials are present or amorphous materials and some crystalline materials with a fine grain size coexist and, accordingly, roughness of an underlayer film after a lateral wall of an etched pattern and a hard mask are removed may be reduced. In addition, when the hard mask is formed with a crystalline structure with a high grain size, it is difficult to remove the hard mask in subsequent processes and, on the other hand, according to the present invention, it is very easy to remove the hard mask due to the reduced grain size.

In the deposition of the metallic carbon film according to the present invention, the thin film may be formed using a single precursor without a separate process gas that reacts with the single precursor and, thus, it may be advantageous that a process parameter is easily adjusted and a structure of a device is simplified.

In the deposition of the metallic carbon film according to the present invention, when the metallic carbon film is formed to a desired thickness on a substrate, the metallic carbon film is divided and deposited into a plurality of layers so as to maintain a remarkably reduced grain size of crystalline materials included in each layer.

In addition, according to the present invention, relative contents of metal and carbon contained in the metallic carbon film may be adjusted to control overall internal stress of the metallic carbon film and to remarkably reduce internal stress, thereby preventing warpage of a substrate.

The foregoing exemplary embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. A deposition method of a metallic carbon film on a heated substrate, the method comprising:
first step of vaporizing a single precursor containing metal and carbon (C);
second step of supplying the vaporized single precursor to a reactor; and
third step of generating plasma in the reactor to decompose the vaporized single precursor and depositing the metallic carbon film on the heated substrate.

2. The method according to claim 1, wherein the metal of the single precursor is tungsten (W).

3. The method according to claim 1, wherein the single precursor further comprises nitrogen (N).

4. The method according to claim 3, wherein the single precursor is TBIDMW [bis(tert-butyl-imido) bis(dimethyl-amido)tungsten].

5. The method according to claim 2, wherein the atomic percentage of the tungsten in the metallic carbon film is 25% to 50%.

6. The method according to claim 1, wherein the grain size of the metallic carbon film is equal to or less than 3 nm.

7. The method according to claim 6, wherein the metallic carbon film includes amorphous materials.

8. The method according to claim 6, wherein the metallic carbon film includes amorphous materials and crystalline materials simultaneous, wherein the amount of the amorphous materials in the metallic carbon film is greater than the amount of the crystalline materials.

9. The method according to claim 1, wherein the depositing of the metallic carbon film is performed at a temperature of about 300 □ to about 550 □.

10. The method according to claim 1, wherein the supplying the vaporized single precursor to the reactor comprises supplying inert gas containing at least one of helium (He) and argon (Ar) to the reactor along with the vaporized single precursor.

11. The method according to claim 1, wherein the metallic carbon film is a hard mask film.

12. The method according to claim 1, further comprising, after the metallic carbon film is deposited, supplying helium (He) to the reactor to generate plasma.

13. The method according to claim 1, wherein at least one of the supplying amount of the single precursor in the first step and the plasma generating period in the third step is adjusted.

14. The method according to claim 13, wherein the supply amount of the single precursor is periodically changed.

15. The method according to claim 14, wherein the periodically changing of the supply amount of the single precursor comprises supplying a predetermined flow rate of the single precursor and non-supplying the single precursor.

16. The method according to claim 14, wherein the plasma is constantly maintained during deposition of the metallic carbon film.

17. The method according to claim 13, wherein the supplying plasma and the non-supplying plasma are periodically repeated during the deposition of the metallic carbon film.

18. The method according to claim 13, wherein the plasma generating period or the supply amount of the single precursor is adjusted to control content of tungsten or carbon in the metallic carbon film.

19. The method according to claim 13, wherein the adjusting of the plasma generating period comprises supplying the single precursor to the reactor when the plasma is supplied and non-supplying the single precursor to the reactor when the plasma is not supplied.

20. The method according to claim 13, further comprising, after the metallic carbon film is deposited, supplying helium (He) to the reactor to generate plasma.
